(19) United States
(12) Patent Application Publication
(10) Pub. No.: US 2025/0192085 A1
(43) Pub. Date: Jun. 12, 2025

(54) SEMICONDUCTOR PACKAGE

(71) Applicant: Samsung Electronics Co., Ltd., Suwon-si (KR)

(72) Inventor: Hyunsoo Chung, Suwon-si (KR)

(21) Appl. No.: 18/885,622

(22) Filed: Sep. 14, 2024

(30) Foreign Application Priority Data
Dec. 11, 2023 (KR) 10-2023-0178967

(51) Int. Cl. H01L 23/00; H01L 25/16; H10B 80/00

(52) U.S. Cl. CPC H01L 24/08; H01L 24/05; H01L 24/24; H01L 25/16; H10B 80/00; H01L 2224/05573; H01L 2224/08145; H01L 2224/24146; H01L 2224/24265; H01L 2924/1431; H01L 2924/1436; H01L 2924/1437; H01L 2924/182; H01L 2924/19104

(57) ABSTRACT

A semiconductor package includes a logic die having a first planar area, a cache memory die on the logic die and having the first planar area, a main memory die stack structure on the cache memory die and including main memory dies stacked in a vertical direction and having a second planar area smaller than the first planar area, and a mold on the cache memory die and covering sidewalls of the main memory dies.

### CROSS-REFERENCE TO RELATED APPLICATION(S)

This application claims priority under 35 U.S.C. § 119 to Korean Patent Application No. 10-2023-0178967, filed on Dec. 11, 2023 in the Korean Intellectual Property Office (KIPO), the disclosure of which is herein incorporated by reference in its entirety.

### BACKGROUND

### 1. Field

Example embodiments relate to a semiconductor package. More particularly, example embodiments relate to a 3-dimensional integrated circuit (3D-IC) package.

### 2. Description of the Related Art

A 3D-IC package may include a logic die, a cache memory die on the logic die, and a main memory die that is disposed on the logic die and spaced apart from the cache memory die in a horizontal direction. In the 3D-IC package, a method of increasing the communication speed between the cache memory die and the main memory die is needed.

### SUMMARY

Example embodiments provide a semiconductor package having enhanced electrical characteristics.

According to example embodiments, there is provided a semiconductor package. The semiconductor package may include a logic die having a first planar area, a cache memory die on the logic die and having the first planar area, a main memory die stack structure on the cache memory die and including main memory dies stacked in a vertical direction and having a second planar area smaller than the first planar area, and a mold on the cache memory die and covering sidewalls of the main memory dies.

According to example embodiments, there is provided a semiconductor package. The semiconductor package may include a logic die, a cache memory die on the logic die and including a first substrate and a redistribution layer (RDL) on the first substrate and containing a redistribution wiring structure, a main memory die stack structure on the cache memory die and including main memory dies stacked in a vertical direction, an inactive element on the cache memory die and being spaced apart from the main memory die stack structure in a horizontal direction, and a mold on the cache memory die and covering sidewalls of the main memory dies and a sidewall and an upper surface of the inactive element. The redistribution wiring structure may be electrically connected to the main memory die stack structure and the inactive element.

According to example embodiments, there is provided a semiconductor package. The semiconductor package may include a logic die, a cache memory die, a main memory die stack structure, an inactive element and a mold. The logic die may have a first planar area, and may include a first substrate having first and second surfaces opposite to each other in a vertical direction, a logic device on the first surface of the first substrate, and a power rail beneath the second surface of the first substrate. The cache memory die may be disposed on the logic die, and may have the first planar area. The cache memory die may include a second substrate having first and second surfaces opposite to each other in the vertical direction, a memory device beneath the first surface of the second substrate, and a redistribution layer (RDL) on the second surface of the second substrate and containing a redistribution wiring structure. The main memory die stack structure may be disposed on the cache memory die. The main memory die stack structure may include main memory dies stacked in the vertical direction, and may have a second planar area smaller than the first planar area. The inactive element may be disposed on the cache memory die, and may be spaced apart from the main memory die stack structure in a horizontal direction. The mold may be disposed on the cache memory die, and may cover sidewalls of the main memory dies and a sidewall and an upper surface of the inactive element.

The semiconductor package in accordance with example embodiments may have an enhanced operation speed and an efficient supply of power.

### BRIEF DESCRIPTION OF THE DRAWINGS

FIG. 1 is a cross-sectional view illustrating a semiconductor package in accordance with example embodiments.

FIGS. 2 to 7 are cross-sectional views illustrating a method of manufacturing a semiconductor package in accordance with example embodiments.

FIG. 8 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

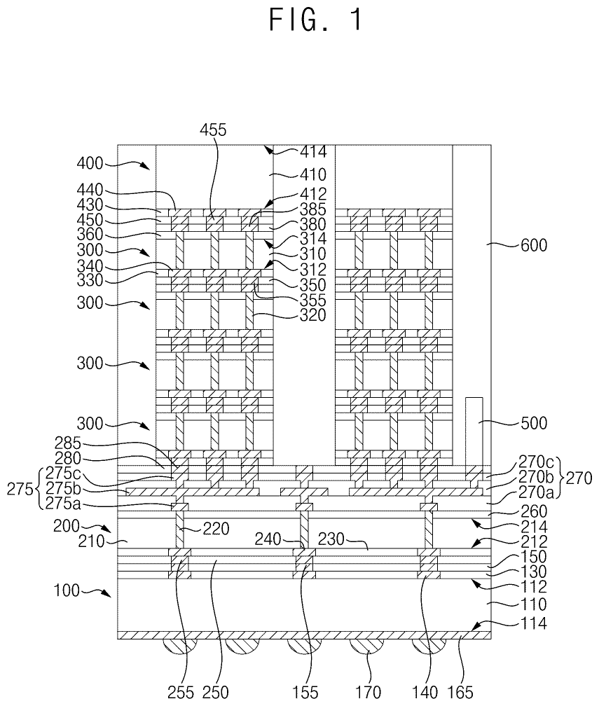

FIG. 1 is a cross-sectional view illustrating a semiconductor package in accordance with example embodiments.

Referring to FIG. 1, the semiconductor package may include first and second semiconductor chips 100 and 200 stacked in the vertical direction, a main memory chip stack structure on the second semiconductor chip 200, an inactive element 500 on a portion of the second semiconductor chip 200 adjacent to the main memory chip stack structure, and a mold 600 that may be disposed on the second semiconductor chip 200 and cover a sidewall of the main chip stack structure and an upper surface and a sidewall of the inactive element 500, and the main chip stack structure may include a plurality of third semiconductor chips 300 stacked in the vertical direction, and a fourth semiconductor chip 400 on an uppermost one of the third semiconductor chips 300.

In example embodiments, the first semiconductor chip 100 may be a buffer die, and may include a logic device such as a controller, and the second semiconductor chip 200 may include a cache memory device such as a static random access memory (SRAM) device. Additionally, each of the third and fourth semiconductor chips 300 and 400 may be a core die, and may include a main memory device such as a dynamic RAM (DRAM) device.

Thus, the first semiconductor chip 100 may also be referred to as a logic die or a logic chip, the second semiconductor chip 200 may also be referred to as a cache memory die or a cache memory chip, and each of the third and fourth semiconductor chips 300 and 400 may also be referred to as a main memory die or a main memory chip. Additionally, the main memory chip stack structure may also be referred to as a main memory die stack structure.

The third semiconductor chip 300 may be a middle core die, and the fourth semiconductor chip 400 may be a top core die. FIG. 1 shows that the main memory chip stack structure includes four third semiconductor chips 300 stacked in the vertical direction, however, the inventive concept may not be limited thereto, and the main memory chip stack structure may include, e.g., more than four third semiconductor chips 300.

FIG. 1 also shows that two main memory chip stack structures are spaced apart from each other in the horizontal direction on the second semiconductor chip 200, however, the inventive concept may not be limited thereto, and for example, one main memory chip stack structure or more than two main memory chip stack structures may be disposed on the second semiconductor chip 200.

Additionally, FIG. 1 shows that a single second semiconductor chip 200 is disposed on the first semiconductor chip 100, however, the inventive concept may not be limited thereto, and more than one second semiconductor chips 200 may be stacked on the first semiconductor chip 100.

In example embodiments, the semiconductor package may be a 3D-IC package having a high bandwidth memory (HBM) package including a logic die and a core die, and a cache memory die.

The first semiconductor chip 100 may include a first substrate 110 having first and second surfaces 112 and 114 opposite to each other in the vertical direction, a first insulating interlayer, a second insulating interlayer 130 and a first bonding layer 150 sequentially stacked in the vertical direction on the first surface 112 of the first substrate 110, a power rail 165 beneath the second surface 114 of the first substrate 110, a fifth insulating interlayer covering a sidewall and a portion of a lower surface of the power rail 165, and a first conductive connection member 170 contacting the lower surface of the power rail 165.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

The first substrate 110 may have a first planar area in the horizontal direction.

A circuit device, e.g., a logic device may be formed on the first surface 112 of the first substrate 110, and thus the first surface 112 may be active surface of the first substrate 110. The circuit device may include circuit patterns, which may be covered by the first insulating interlayer. The circuit patterns may include, e.g., a gate structure, a source/drain layer, a lower contact plug, etc.

The second insulating interlayer 130 may contain a first wiring structure 140 therein. The first wiring structure 140 may include, e.g., wirings, vias, contact plugs, etc., at a plurality of levels, however, the first wiring structure 140 is shown as a single structure in FIG. 1 for the brevity of the drawing.

The first insulating interlayer and the second insulating interlayer 130 may include, e.g., silicon oxide or a low-k dielectric material such as an oxide doped with carbon or a fluorine. The wirings, the vias and the contact plugs may include a conductive material, e.g., a metal, a metal nitride, a metal silicide, etc.

The first bonding layer 150 may contain a first bonding pattern 155 therein, and may cover a sidewall of the first bonding pattern 155. In example embodiments, a plurality of first bonding patterns 155 may be spaced apart from each other in the horizontal direction in the first bonding layer 150. The first bonding pattern 155 may include a metal, e.g., copper, and the first bonding layer 150 may include an insulating nitride, e.g., silicon carbonitride, or an oxide, e.g., silicon oxide.

The power rail 165 may be disposed beneath the second surface 114 of the first substrate 110, and may contact the lower contact plug extending through the first substrate 110 to be electrically connected thereto. The sidewall and the portion of the lower surface of the power rail 165 may be covered by the fifth insulating interlayer. The power rail 165 may include, e.g., a metal, a metal nitride, a metal silicide, etc.

The first conductive connection member 170 may be disposed beneath the fifth insulating interlayer and the power rail 165, and may contact the power rail 165 to be electrically connected thereto. In example embodiments, a plurality of first conductive connection members 170 may be spaced apart from each other in the horizontal direction. The first conductive connection member 170 may be a conductive bump including, e.g., solder.

The second semiconductor chip 200 may include a second substrate 210 having first and second surfaces 212 and 214 opposite to each other in the vertical direction, a first through electrode 220 extending through the second substrate 210, a third insulating interlayer, a fourth insulating interlayer 230 and a second bonding layer 250 sequentially stacked downwardly in the vertical direction beneath the first surface 212 of the second substrate 210, a first protective pattern structure 260 on the second surface 214 of the second substrate 210, and a redistribution layer (RDL) on the first protective pattern structure 260 and the first through electrode 220.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

In example embodiments, the second substrate 210 may have the first planar area in the horizontal direction as the first substrate 110.

A circuit device, e.g., an SRAM device may be formed on the first surface 212 of the second substrate 210, and thus the first surface 212 of the second substrate 210 facing the first semiconductor chip 100 may be an active surface. The circuit device may include circuit patterns, which may be covered by the third insulating interlayer.

The fourth insulating interlayer 230 may contain a second wiring structure 240 therein. The second wiring structure 240 may include, e.g., wirings, vias, contact plugs, etc., at a plurality of levels, however, the second wiring structure 240 is shown as a single structure in FIG. 1 for the brevity of the drawing.

The third insulating interlayer and the fourth insulating interlayer 230 may include, e.g., silicon oxide or a low-k dielectric material such as an oxide doped with carbon or a fluorine.

The second bonding layer 250 may contain a second bonding pattern 255 therein, and may cover a sidewall of the second bonding pattern 255. In example embodiments, a plurality of second bonding patterns 255 may be spaced apart from each other in the horizontal direction in the second bonding layer 250. The second bonding layer 250 may be bonded with the first bonding layer 150, and the second bonding patterns 255 may contact the first bonding patterns 155, respectively. The second bonding pattern 255 may include a metal, e.g., copper, and the second bonding layer 250 may include an insulating nitride, e.g., silicon carbonitride, or an oxide, e.g., silicon oxide.

The first through electrode 220 may extend through the second substrate 210 in the vertical direction, and may include a protrusion portion that may protrude upwardly in the vertical direction over the second surface 214 of the second substrate 210. In example embodiments, a plurality of first through electrodes 220 may be spaced apart from each other in the horizontal direction, and each of the first through electrodes 220 may have a shape of, e.g., a circle, an ellipse, a polygon, a polygon with rounded corners, etc., in a plan view.

In an example embodiment, the first through electrode 220 may extend through the second substrate 210, and may contact a portion of the circuit patterns in the third insulating interlayer to be electrically connected thereto. Alternatively, the first through electrode 220 may extend through the second substrate 210 and the third insulating interlayer, and may contact a portion of the second wiring structure 240 in the fourth insulating interlayer 230 to be electrically connected thereto.

The first through electrode 220, and the wirings, the vias and the contact plugs of the second wiring structure 240 may include a conductive material, e.g., a metal, a metal nitride, a metal silicide, etc.

The first protective pattern structure 260 may be formed on the second surface 214 of the second substrate 210, and may surround the protrusion portion of the first through electrode 220. In an example embodiment, the first protective pattern structure 260 may include first and second protective patterns stacked in the vertical direction. The first protective pattern may include an oxide, e.g., silicon oxide, and the second protective pattern may include an insulating nitride, e.g., silicon nitride.

In an example embodiment, the RDL 270 may include first to third insulation layers 270a, 270b and 270c sequentially stacked in the vertical direction, and a redistribution wiring structure 275 including conductive structures in the first to third insulation layers 270a, 270b and 270c. However, the inventive concept may not be limited thereto, and the RDL 270 may include more or less than three insulation layers, and the redistribution wiring structure 275 may include conductive structures in more or less than three insulation layers. A vertical layout of the conductive structures of the redistribution wiring structure 275 shown in FIG. 1 is illustrative, and the conductive structures of the redistribution wiring structure 275 may have another vertical layout.

The redistribution wiring structure 275 may include a first conductive pad 275a and first and second wirings 275b and 275c sequentially stacked in the vertical direction. A lower surface of a portion of the first wiring 275b may contact an upper surface of a portion of the first conductive pad 275a serving as a conductive pad. A portion of the second wiring 275c may serve as a third conductive pad.

The first conductive pad 275a may be formed in the first insulation layer 270a, and a portion of an upper surface and a sidewall of the first conductive pad 275a may be covered by the first insulation layer 270a. A lower surface of the first conductive pad 275a may contact an upper surface of the first through electrode 220 to be electrically connected thereto. The first wiring 275b may be formed in the second insulation layer 270b, and a portion of an upper surface and a sidewall of the first wiring 275b may be covered by the second insulation layer 270b. The second wiring 275c may be formed in the third insulation layer 270c, and a sidewall of the second wiring 275c may be covered by the third insulation layer 270c.

In example embodiments, each of the first to third insulation layers 270a, 270b and 270c may include an organic material, e.g., a polymer such as polyimide. Each of the first conductive pad 275a and the first and second wirings 275b and 275c may include, e.g., aluminum, copper, tin, nickel, gold, platinum, etc., or an alloy thereof.

The third bonding layer 280 may be formed on the RDL 270. The third bonding layer 280 may contain a third bonding pattern 285 therein, and may cover a sidewall of the third bonding pattern 285. In example embodiments, a plurality of third bonding patterns 285 may be spaced apart from each other in the horizontal direction. The third bonding patterns 285 may contact the third conductive pads (i.e., 275c), respectively, in the RDL 270. The third bonding pattern 285 may include a metal, e.g., copper, and the third bonding layer 280 may include an insulating nitride, e.g., silicon carbonitride, or an oxide, e.g., silicon oxide.

Although not shown, the first semiconductor chip 100 may include a third through electrode extending through the first substrate 110. The third through electrode may extend through the first substrate 110 in the vertical direction, and may include a protrusion portion that may protrude upwardly in the vertical direction over the first surface 112 of the first substrate 110. In example embodiments, a plurality of third through electrodes may be spaced apart from each other in the horizontal direction, and each of the third through electrodes may have a shape of, e.g., a circle, an ellipse, a polygon, a polygon with rounded corners, etc., in a plan view. The third through electrode may contact a portion of the first wiring structure 140 in the second insulating interlayer 130 to be electrically connected thereto.

The third semiconductor chip 300 may include a third substrate 310 having first and second surfaces 312 and 314 opposite to each other in the vertical direction, a second through electrode 320 extending through the third substrate 310, a sixth insulating interlayer, a seventh insulating interlayer 330 and a fourth bonding layer 350 sequentially stacked downwardly in the vertical direction beneath the first surface 312 of the third substrate 310, a second protective pattern structure 360 on the second surface 314 of the third substrate 310, and a fifth bonding layer 380 on the second through electrode 320 and the second protective pattern structure 360.

The third substrate 310 may include a semiconductor material, e.g., silicon, germanium, silicon-germanium, or a III-V group compound semiconductor, e.g., GaP, GaAs, GaSb, etc. In example embodiments, the third substrate 310 may be a silicon-on-insulator (SOI) substrate or a germanium-on-insulator (GOI) substrate.

In example embodiments, the third substrate 310 may have a second planar area in the horizontal direction smaller than the first planar area in the horizontal direction.

A circuit device, e.g., a DRAM device may be formed on the first surface 312 of the third substrate 310, and thus the first surface 312 of the third substrate 310 facing the second semiconductor chip 200 may be an active surface. The circuit device may include circuit patterns, which may be covered by the sixth insulating interlayer.

The seventh insulating interlayer 330 may contain a third wiring structure 340 therein. The third wiring structure 340 may include, e.g., wirings, vias, contact plugs, etc., at a plurality of levels, however, the third wiring structure 340 is shown as a single structure in FIG. 1 for the brevity of the drawing.

The sixth insulating interlayer and the seventh insulating interlayer 330 may include, e.g., silicon oxide or a low-k dielectric material such as an oxide doped with carbon or a fluorine.

The fourth bonding layer 350 may be formed beneath the seventh insulating interlayer 330. The fourth bonding layer 350 may contain a fourth bonding pattern 355 therein, and may cover a sidewall of the fourth bonding pattern 355. In example embodiments, a plurality of fourth bonding patterns 355 may be spaced apart from each other in the horizontal direction in the fourth bonding layer 350. The fourth bonding patterns 355 may contact a portion of the third wiring structure 340 disposed in the seventh insulating interlayer 330 to be electrically connected thereto.

In example embodiments, the fourth bonding layer 350 included in a lowermost one of the third semiconductor chips 300 may be bonded with the third bonding layer 280 included in the second semiconductor chip 200, and the fourth bonding patterns 355 may contact the third bonding patterns 285, respectively.

The second through electrode 320 may extend through the third substrate 310 in the vertical direction, and may include a protrusion portion that may protrude upwardly in the vertical direction over the second surface 314 of the third substrate 310. In example embodiments, a plurality of second through electrodes 320 may be spaced apart from each other in the horizontal direction, and each of the second through electrodes 320 may have a shape of, e.g., a circle, an ellipse, a polygon, a polygon with rounded corners, etc., in a plan view.

In an example embodiment, the second through electrode 320 may extend through the third substrate 310, and may contact a portion of the circuit patterns in the sixth insulating interlayer to be electrically connected thereto. Alternatively, the second through electrode 320 may extend through the third substrate 310 and the sixth insulating interlayer, and may contact a portion of the third wiring structure 340 in the seventh insulating interlayer 330 to be electrically connected thereto.

The second through electrode 320, and the wirings, the vias and the contact plugs of the third wiring structure 340 may include a conductive material, e.g., a metal, a metal nitride, a metal silicide, etc.

The second protective pattern structure 360 may be formed on the second surface 314 of the third substrate 310, and may surround the protrusion portion of the second through electrode 320. In an example embodiment, the second protective pattern structure 360 may include third and fourth protective patterns stacked in the vertical direction. The third protective pattern may include an oxide, e.g., silicon oxide, and the fourth protective pattern may include an insulating nitride, e.g., silicon nitride.

The fifth bonding layer 380 may be formed on the second protective pattern structure 360 and the second through electrode 320. The third bonding layer 280 may contain a fifth bonding pattern 385 therein, and may cover a sidewall of the fifth bonding pattern 385. In example embodiments, a plurality of fifth bonding patterns 385 may be spaced apart from each other in the horizontal direction.

In example embodiments, the fourth bonding layer 350 included in a first one of the third semiconductor chips 300 may be bonded with the fifth bonding layer 380 included in a second one of the third semiconductor chips 300 that is disposed under the first one of the third semiconductor chips 300, and the fourth bonding patterns 355 may contact the fifth bonding patterns 385, respectively.

Each of the fourth and fifth bonding patterns 355 and 385 may include a metal, e.g., copper, and each of the fourth and fifth bonding layers 350 and 380 may include an insulating nitride, e.g., silicon carbonitride, or an oxide, e.g., silicon oxide.

The fourth semiconductor chip 400 may include a fourth substrate 410 having first and second surfaces 412 and 414 opposite to each other in the vertical direction, an eighth insulating interlayer, a ninth insulating interlayer 430 and a sixth bonding layer 450 sequentially stacked downwardly in the vertical direction beneath the first surface 412 of the fourth substrate 410.

The fourth substrate 410 may include a semiconductor material, e.g., silicon, germanium, silicon-germanium, or a III-V group compound semiconductor, e.g., GaP, GaAs, GaSb, etc. In example embodiments, the fourth substrate 410 may be a silicon-on-insulator (SOI) substrate or a germanium-on-insulator (GOI) substrate.

In example embodiments, the fourth substrate 410 may have the second planar area in the horizontal direction as the third substrate 310.

In example embodiments, the fourth semiconductor chip 400 may include a memory device having the same function as the third semiconductor chip 300.

When the fourth semiconductor chip 400 is the same chip as the third semiconductor chip 300, a circuit device, e.g., a DRAM device may be formed on the first surface 412 of the fourth substrate 410, and thus the first surface 412 of the fourth substrate 410 facing the third semiconductor chip 300 may be an active surface. The circuit device may include circuit patterns, which may be covered by the eighth insulating interlayer.

The ninth insulating interlayer 430 may contain a fourth wiring structure 440 therein. The fourth wiring structure 440 may include, e.g., wirings, vias, contact plugs, etc., at a plurality of levels, however, the fourth wiring structure 440 is shown as a single structure in FIG. 1 for the brevity of the drawing.

The eighth insulating interlayer and the ninth insulating interlayer 430 may include, e.g., silicon oxide or a low-k dielectric material such as an oxide doped with carbon or a fluorine.

The sixth bonding layer 450 may be formed beneath the ninth insulating interlayer 430. The sixth bonding layer 450 may contain a sixth bonding pattern 455 therein, and may cover a sidewall of the sixth bonding pattern 455. In example embodiments, a plurality of sixth bonding patterns 455 may be spaced apart from each other in the horizontal direction in the sixth bonding layer 450. The sixth bonding patterns 455 may contact a portion of the fourth wiring structure 440 in the ninth insulating interlayer 430 to be electrically connected thereto.

The sixth bonding pattern 455 may include a metal, e.g., copper, and the sixth bonding layer 450 may include an insulating nitride, e.g., silicon carbonitride, or an oxide, e.g., silicon oxide.

The wirings, the vias and the contact plugs included in the fourth wiring structure 440 may include a conductive material, e.g., a metal, a metal nitride, a metal silicide, etc.

In example embodiments, the fourth semiconductor chip 400 may have a thickness in the vertical direction greater than that of the third semiconductor chip 300. Alternatively, the fourth semiconductor chip 400 may be a dummy chip having no memory device therein. In this case, the fourth semiconductor chip 400 may be used as a heat sink. In an embodiment, the fourth semiconductor chip 400 may not include a through electrode.

The inactive element 500 may be formed on the third bonding layer 280 of the second semiconductor chip 200, and may contact the third bonding pattern 285 to be electrically connected thereto. The inactive element 500 may include, e.g., capacitors, resistors, inductors, etc. The inactive element 500 may be a passive device.

FIG. 1 shows a single inactive element 500 on the second semiconductor chip 200, however, the inventive concept may not be limited thereto, and a plurality of inactive elements 500 may be spaced apart from each other in the horizontal direction on the second semiconductor chip 200.

The mold 600 may include, e.g., epoxy molding compound (EMC).

The semiconductor package may be mounted on a module substrate with the first conductive connection member 170 therebetween to form a memory module.

In the semiconductor package, the second semiconductor chip 200 including a cache memory device may be interposed between the first semiconductor chip 100 including a logic device and the third and fourth semiconductor chips 300 and 400 including main memory devices, and thus the logic device, the cache memory device and the main memory device may be sequentially stacked in the vertical direction. The active surface of the first substrate 110 included in the first semiconductor chip 100 and the active surface of the second substrate 210 included in the second semiconductor chip 200 may face each other.

Accordingly, the cache memory device may directly access the logic device and the main memory device so that the semiconductor package may have an enhanced operation speed.

Additionally, the first semiconductor chip 100 may include the power rail 165 disposed beneath a lower surface of the first substrate 110, that is, beneath the second surface 114 of the first substrate 110, and thus the power rail 165 may efficiently provide power.

The second semiconductor chip 200 may include the RDL 270 on the second surface 214 of the second substrate 210, and may communicate with the third and fourth semiconductor chips 300 and 400 and the inactive element 500 through the RDL 270 containing the redistribution wiring structure 275. For example, the RDL 270 may serve as an interposer.

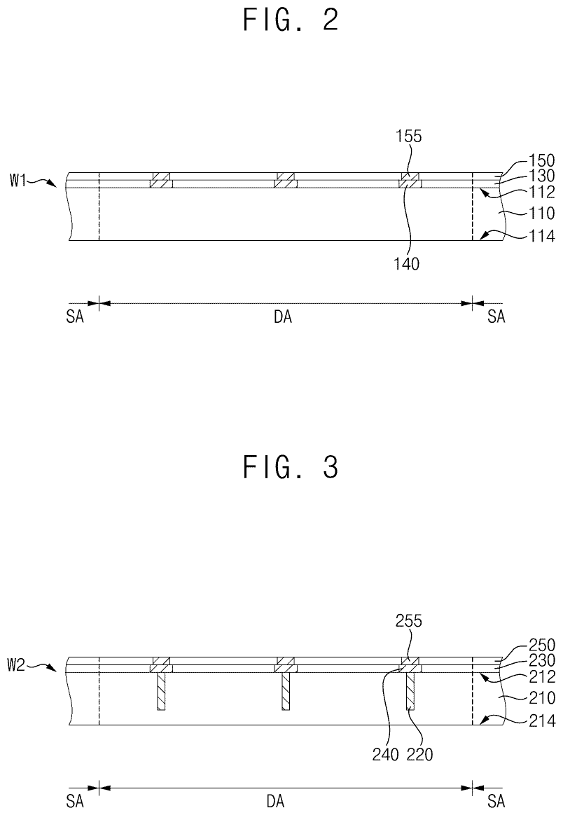

FIGS. 2 to 7 are cross-sectional views illustrating a method of manufacturing a semiconductor package in accordance with example embodiments.

Referring to FIG. 2, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns. A second insulating interlayer 130 may be formed on the first insulating interlayer, and may contain a first wiring structure 140 therein.

A first bonding layer 150 containing a first bonding pattern 155 may be formed on the second insulating interlayer 130. The first bonding pattern 155 may contact an upper surface of a portion of the first wiring 140 to be electrically connected thereto.

Although not shown, a third through electrode extending through an upper portion of the first substrate 110 in the vertical direction and contacting a portion of the circuit patterns to be electrically connected thereto may be formed.

Referring to FIG. 3, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process to be singulated into a plurality of second semiconductor chips.

In the die region DA, a circuit device may be formed on the first surface 212 of the second substrate 210. The circuit device may include a memory device, particularly, an SRAM device. The circuit device may include circuit patterns, and a third insulating interlayer may be formed on the first surface 212 of the second substrate 210 to cover the circuit patterns. A fourth insulating interlayer 230 may be formed on the third insulating interlayer, and may contain a second wiring structure 240 therein.

A second bonding layer 250 containing a second bonding pattern 255 therein may be formed on the fourth insulating interlayer 230. The second bonding pattern 255 may contact an upper surface of a portion of the second wiring structure 240 to be electrically connected thereto.

A first through electrode 220 extending through an upper portion of the second substrate 210 in the vertical direction and contacting a portion of the circuit patterns to be electrically connected thereto may be formed.

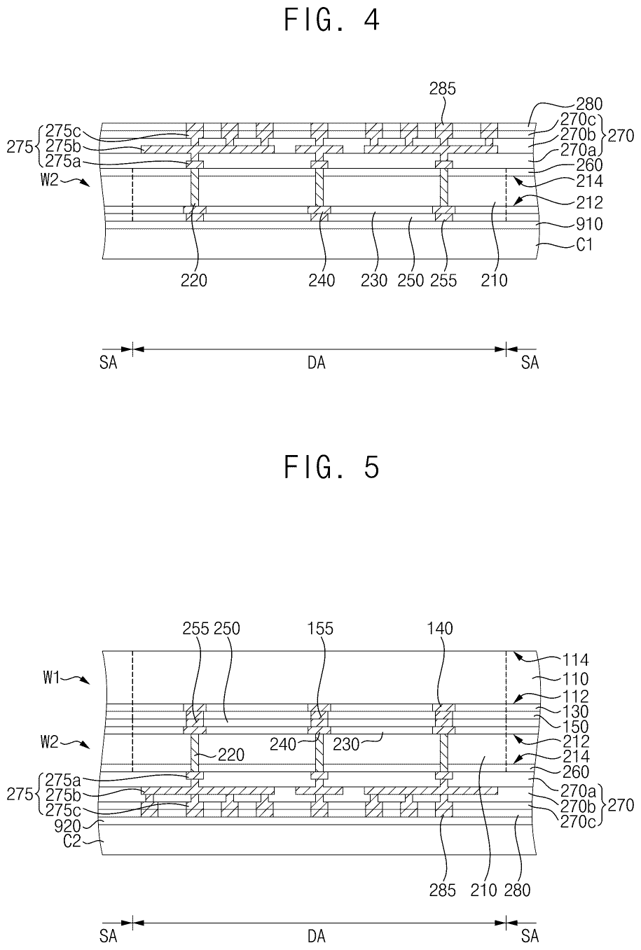

Referring to FIG. 4, a first temporary bonding layer 910 may be attached on a first carrier substrate C1, the first carrier substrate C1 may be bonded with the second wafer W2 such that the first temporary bonding layer 910 may contact an upper surface of the second bonding layer 250, and a structure including the first carrier substrate C1 and the second wafer W2 may be overturned.

The first carrier substrate C1 may include, e.g., a metallic or non-metallic plate, a silicon substrate, a glass substrate, etc. The first temporary bonding layer 910 may include a material that may lose adhesion by irradiation of light or heating. In an example embodiment, the first temporary bonding layer 910 may include a release tape.

A portion of the second substrate 210 adjacent to the second surface 214 of the second substrate 210 may be removed by, e.g., a grinding process to expose an upper portion of the first through electrode 220, a first protective layer structure may be formed on the second surface 214 of the second substrate 210 to cover the first through electrode 220, and a planarization process may be performed on the first protective layer structure until an upper surface of the first through electrode 220 is exposed, so as to form a first protective pattern structure 260.

In example embodiments, the planarization process may include a chemical mechanical polishing (CMP) process and/or an etch back process.

A redistribution layer (RDL) 270 containing a redistribution wiring structure 275 may be formed on the first through electrode 220 and the first protective pattern structure 260.

A third bonding layer 280 containing a third bonding pattern 285 may be formed on the RDL 270. The third bonding pattern 285 may contact an upper surface of a third conductive pad included in the redistribution wiring structure 275 to be electrically connected thereto.

Referring to FIG. 5, a second temporary bonding layer 920 may be attached on a second carrier substrate C2, the second carrier substrate C2 may be bonded with the second wafer W2 such that the second temporary bonding layer 920 may contact an upper surface of the third bonding layer 280, and a structure including the first and second carrier substrates C1 and C2 and the second wafer W2 may be overturned.

The second carrier substrate C2 may include, e.g., a metallic or non-metallic plate, a silicon substrate, a glass substrate, etc. The second temporary bonding layer 920 may include a material that may lose adhesion by irradiation of light or heating. In an example embodiment, the second temporary bonding layer 910 may include a release tape.

The first temporary bonding layer 910 attached to the first carrier substrate C1 may be separated from the second bonding layer 250 and the second bonding pattern 255 so that the first carrier substrate C1 may be separated from the second wafer W2, and the first wafer W1 and the second wafer W2 may be bonded with each other by a hybrid copper bonding (HCB) process.

In example embodiments, the first bonding layer 150 of the first wafer W1 may contact the second bonding layer 250 of the second wafer W2 so that the first and second wafers W1 and W2 may be bonded with each other, and the first bonding pattern 155 in the first bonding layer 150 may contact the second bonding pattern 255 in the second bonding layer 250.

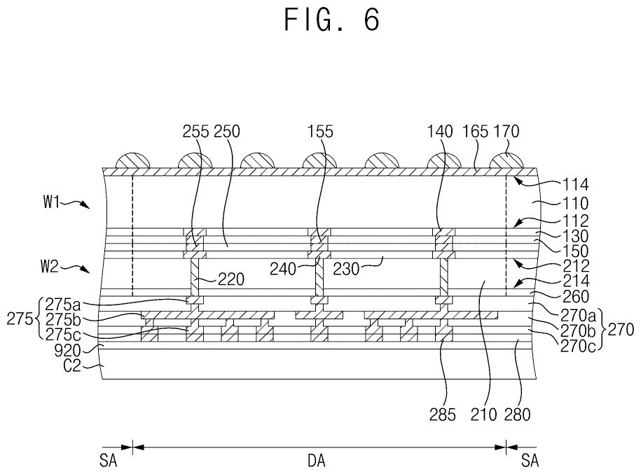

Referring to FIG. 6, a power rail 165 may be formed on the second surface 114 of the first wafer W1, and a first conductive connection member 170 may be formed to contact an upper surface of the power rail 165.

In example embodiments, after forming a lower contact plug extending through the first wafer W1 to contact a source/drain layer or an upper contact plug included in the logic device, the power rail 165 may be formed to contact the lower contact plug. A fifth insulating interlayer may be further formed to cover a sidewall and a portion of an upper surface of the power rail 165.

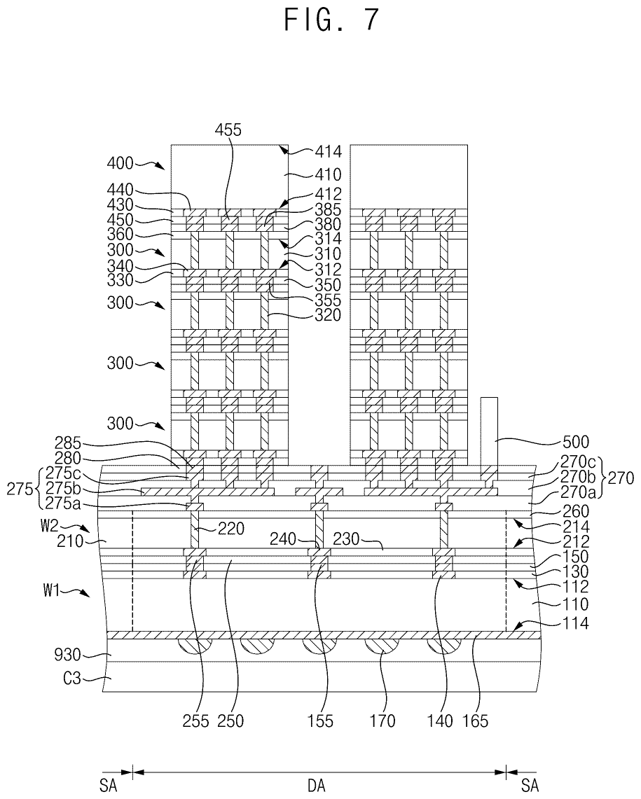

Referring to FIG. 7, a third temporary bonding layer 930 may be attached on a third carrier substrate C3, the third carrier substrate C3 may be bonded with the first wafer W1 such that the third temporary bonding layer 930 may contact an upper surface of the fifth insulating interlayer to cover the first conductive connection member 170, and a structure including the second and third carrier substrates C2 and C3 and the first and second wafers W1 and W2 may be overturned.

The third carrier substrate C3 may include, e.g., a metallic or non-metallic plate, a silicon substrate, a glass substrate, etc. The third temporary bonding layer 930 may include a material that may lose adhesion by irradiation of light or heating. In an example embodiment, the third temporary bonding layer 930 may include glue.

The second temporary bonding layer 920 attached to the second carrier substrate C2 may be separated from the third bonding layer 280 and the third bonding pattern 285 so that the second carrier substrate C2 may be separated from the second wafer W2, and a plurality of third semiconductor chips 300 and a fourth semiconductor chip 400 may be stacked on the second wafer W2 to be bonded with each other, which may collectively form a main memory chip stack structure.

The third semiconductor chip 300 may include a third substrate 310 having first and second surfaces 312 and 314 opposite to each other in the vertical direction. A circuit device may be formed on the first surface 312 of the third substrate 310. The circuit device may include a memory device, particularly, a DRAM device. The circuit device may include circuit patterns, and a sixth insulating interlayer may be formed on the first surface 312 of the third substrate 310 to cover the circuit patterns. A seventh insulating interlayer 330 may be formed beneath the sixth insulating interlayer, and may contain a third wiring structure 340 therein.

A fourth bonding layer 350 containing a fourth bonding pattern 355 therein may be formed on the seventh insulating interlayer 330. The fourth bonding pattern 355 may contact a lower surface of a portion of the third wiring structure 340 to be electrically connected thereto.

A second through electrode 320 extending through an upper portion of the third substrate 310 in the vertical direction and contacting a portion of the circuit patterns to be electrically connected thereto may be formed. The second through electrode 320 may include a protrusion portion protruding over the second surface 314 of the third substrate 310.

A second protective pattern structure 360 covering the protrusion portion of the second through electrode 320 may be formed on the second surface 314 of the third substrate 310.

A fifth bonding layer 380 containing a fifth bonding pattern 385 therein may be formed on the second protective pattern structure 360 and the second through electrode 320. The fifth bonding pattern 385 may contact an upper surface of the second through electrode 320 to be electrically connected thereto.

The fourth semiconductor chip 400 may include a fourth substrate 410 having first and second surfaces 412 and 414 opposite to each other in the vertical direction. A circuit device may be formed on the first surface 412 of the fourth substrate 410. The circuit device may include a memory device, particularly, a DRAM device. The circuit device may include circuit patterns, and an eighth insulating interlayer may be formed on the first surface 412 of the fourth substrate 410 to cover the circuit patterns. A ninth insulating interlayer 430 may be formed beneath the eighth insulating interlayer, and may contain a fourth wiring structure 440 therein.

A sixth bonding layer 450 containing a sixth bonding pattern 455 therein may be formed beneath the ninth insulating interlayer 430. The sixth bonding pattern 455 may contact a lower surface of a portion of the fourth wiring structure 440 to be electrically connected thereto.

In example embodiments, each of the third and fourth semiconductor chips 300 and 400 may be stacked on the second wafer W2 such that each of the first surfaces 312 and 412 of the third and fourth semiconductor chips 300 and 400 may face downwardly. The third semiconductor chip 300 and the second wafer W2, and the third semiconductor chips 300, and the fourth semiconductor chip 400 and the third semiconductor chip 300 may be bonded with each other by an HCB process.

Thus, the fourth bonding layer 350 of the third semiconductor chip 300 and the third bonding layer 280 of the second wafer W2 may be bonded with each other, and the fourth bonding pattern 355 and the third bonding pattern 285 may contact each other. The fourth bonding layer 350 of a first one of the third semiconductor chips 300 and the fifth bonding layer 380 of a second one of the third semiconductor chips 300 that is disposed under the first one of the third semiconductor chips 300 may be bonded with each other, and the fourth bonding pattern 355 and the fifth bonding pattern 385 may contact each other. Additionally, the sixth bonding layer 450 of the fourth semiconductor chip 400 and the fifth bonding layer 380 of an uppermost one of the third semiconductor chips 300 may be bonded with each other, and the sixth bonding pattern 455 and the fifth bonding pattern 385 may contact each other.

An inactive element 500 may be formed on the third bonding layer 280 of the second wafer W2, and the inactive element 500 may contact the third bonding pattern 285 in the third bonding layer 280 to be electrically connected thereto.

Referring to FIG. 1 again, a mold layer may be formed on the second wafer W2 to cover the main memory chip stack structure and the inactive element 500, and a planarization process may be performed on the mold layer until an upper surface of the main memory chip stack structure is exposed, and thus a mold 600 covering a sidewall of the main memory chip stack structure and an upper surface and a sidewall of the inactive element 500 may be formed.

In example embodiments, the planarization process may include a CMP process.

The first and second wafers W1 and W2 may be cut along the scribe lane region SA by, e.g., a sawing process to be singulated into a plurality of first semiconductor chips 100 and a plurality of second semiconductor chips 200, respectively.

During the sawing process, the mold 600 may also be cut to be formed on each of the second semiconductor chips 200, and may cover the sidewall of the main memory chip stack structure and the upper surface and the sidewall of the inactive element 500.

The third temporary bonding layer 930 attached to the third carrier substrate C3 may be separated from the fifth insulating interlayer, the power rail 165 and the first conductive connection member 170 so that the third carrier substrate C3 may be separated from each of the first semiconductor chips 100. Thus, the manufacturing the semiconductor package may be completed.

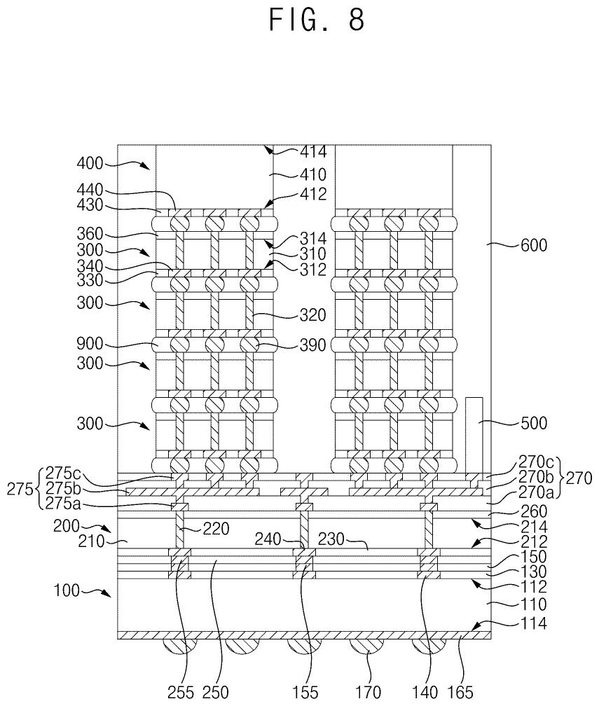

FIG. 8 is a cross-sectional view illustrating a semiconductor package in accordance with example embodiments, which may correspond to FIG. 1. The semiconductor package may be substantially the same as or similar to that of FIG. 1, except for the bonding process of the semiconductor chips, and thus repeated explanations are omitted herein.

Referring to FIG. 8, the third semiconductor chip 300 and the second semiconductor chip 200, the third semiconductor chips 300, and the fourth semiconductor chip 400 and the third semiconductor chip 300 may be bonded with each other by a thermal compression bonding (TCB) process.

Thus, the second semiconductor chip 200 may not include the third bonding layer 280 and the third bonding pattern 285, the third semiconductor chip 300 may not include the fourth and fifth bonding layers 350 and 380 and the fourth and fifth bonding patterns 355 and 385, and the fourth semiconductor chip 400 may not include the sixth bonding layer 450 and the sixth bonding pattern 455.

Instead, an adhesion layer 900 and a second conductive connection member 390 may be formed between the second and third semiconductor chips 200 and 300, between the third semiconductor chips 300, and between the third and fourth semiconductor chips 300 and 400.

In some embodiments, some of the third semiconductor chip 300 and the second semiconductor chip 200, the third semiconductor chips 300, and the fourth semiconductor chip 400 and the third semiconductor chip 300 may be bonded with each other by an HCB process and others thereof may be bonded with each other by a TCB process.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the present invention as defined in the appended claims.

What is claimed is:

1. A semiconductor package comprising:
a logic die having a first planar area;
a cache memory die on the logic die, the cache memory die having the first planar area;
a main memory die stack structure on the cache memory die, the main memory die stack structure including main memory dies stacked in a vertical direction and having a second planar area smaller than the first planar area; and
a mold on the cache memory die, the mold covering sidewalls of the main memory dies.

2. The semiconductor package according to claim 1, further comprising:
an inactive element on the cache memory die, the inactive element being spaced apart from the main memory die stack structure in a horizontal direction,
wherein the mold covers a sidewall and an upper surface of the inactive element.

3. The semiconductor package according to claim 2, wherein the cache memory die includes:
a substrate; and
a redistribution layer (RDL) on the substrate, the RDL containing a redistribution wiring structure therein, and
wherein the redistribution wiring structure is electrically connected to the main memory die stack structure and the inactive element.

4. The semiconductor package according to claim 3, wherein the cache memory die further includes a through electrode extending through the substrate and being electrically connected to the redistribution wiring structure.

5. The semiconductor package according to claim 1, wherein the logic die includes:
a first substrate having first and second surfaces opposite to each other in the vertical direction, the first surface facing the cache memory die;
a logic device on the first surface of the first substrate; and
a power rail beneath the second surface of the first substrate.

6. The semiconductor package according to claim 5, wherein the cache memory die includes:
a second substrate having first and second surfaces opposite to each other in the vertical direction, the first surface facing the logic die; and
a memory device on the first surface of the second substrate.

7. The semiconductor package according to claim 6, wherein the memory device includes a static random access memory (SRAM) device.

8. The semiconductor package according to claim 6, wherein each of the main memory dies includes:
a third substrate having first and second surfaces opposite to each other in the vertical direction, the first surface facing the cache memory die; and
a memory device on the first surface of the third substrate.

9. The semiconductor package according to claim 8, wherein the memory device includes a dynamic random access memory (DRAM) device.

10. The semiconductor package according to claim 1, wherein:
the logic die includes:
a first substrate; and
a first bonding pattern on the first substrate and a first bonding layer containing the first bonding pattern,
the cache memory die includes:
a second substrate; and
a second bonding pattern beneath the second substrate and a second bonding layer containing the second bonding pattern, and
the first and second bonding layers are bonded with each other, and the first and second bonding patterns contact each other.

11. The semiconductor package according to claim 1, wherein:
the cache memory die includes:
a first substrate; and
a first bonding pattern on the first substrate and a first bonding layer containing the first bonding pattern,
a lowermost one of the main memory dies includes:
a second substrate; and
a second bonding pattern beneath the second substrate and a second bonding layer containing the second bonding pattern, and
the first and second bonding layers are bonded with each other, and the first and second bonding patterns contact each other.

12. A semiconductor package comprising:
a logic die;
a cache memory die on the logic die, the cache memory die including:
a first substrate; and
a redistribution layer (RDL) on the first substrate, the RDL containing a redistribution wiring structure;
a main memory die stack structure on the cache memory die, the main memory die stack structure including main memory dies stacked in a vertical direction;
an inactive element on the cache memory die, the inactive element being spaced apart from the main memory die stack structure in a horizontal direction; and
a mold on the cache memory die, the mold covering sidewalls of the main memory dies and a sidewall and an upper surface of the inactive element,
wherein the redistribution wiring structure is electrically connected to the main memory die stack structure and the inactive element.

13. The semiconductor package according to claim 12, wherein the cache memory die further includes a through electrode extending through the first substrate and being electrically connected to the redistribution wiring structure.

14. The semiconductor package according to claim 12, wherein the logic die includes:
a second substrate having first and second surfaces opposite to each other in the vertical direction, the first surface facing the cache memory die;
a logic device on the first surface of the second substrate; and
a power rail beneath the second surface of the second substrate.

15. The semiconductor package according to claim 12, wherein each of the main memory dies includes:
a second substrate having first and second surfaces opposite to each other in the vertical direction, the first surface facing the cache memory die; and
a memory device on the first surface of the second substrate.

16. The semiconductor package according to claim 12, wherein:
the cache memory die includes:
a first bonding pattern beneath the first substrate; and
a first bonding layer containing the first bonding pattern,
the logic die includes:
a second substrate; and
a second bonding pattern on the second substrate and a second bonding layer containing the second bonding pattern, and
the first and second bonding layers are bonded with each other, and the first and second bonding patterns contact each other.

17. The semiconductor package according to claim 12, wherein:
the cache memory die includes:
a first bonding pattern on the RDL; and
a first bonding layer containing the first bonding pattern,
a lowermost one of the main memory dies includes:
a second substrate; and
a second bonding pattern beneath the second substrate and a second bonding layer containing the second bonding pattern, and
the first and second bonding layers are bonded with each other, and the first and second bonding patterns contact each other.

18. A semiconductor package comprising:
a logic die having a first planar area, the logic die including:
a first substrate having first and second surfaces opposite to each other in a vertical direction;
a logic device on the first surface of the first substrate; and
a power rail beneath the second surface of the first substrate;
a cache memory die on the logic die, the cache memory die having the first planar area and including:
a second substrate having first and second surfaces opposite to each other in the vertical direction;
a memory device beneath the first surface of the second substrate; and
a redistribution layer (RDL) on the second surface of the second substrate, the RDL containing a redistribution wiring structure;
a main memory die stack structure on the cache memory die, the main memory die stack structure including main memory dies stacked in the vertical direction and having a second planar area smaller than the first planar area;
an inactive element on the cache memory die, the inactive element being spaced apart from the main memory die stack structure in a horizontal direction; and
a mold on the cache memory die, the mold covering sidewalls of the main memory dies and a sidewall and an upper surface of the inactive element.

19. The semiconductor package according to claim 18, wherein the first surface of the first substrate and the first surface of the second substrate face each other.

20. The semiconductor package according to claim 18, wherein the redistribution wiring structure is electrically connected to the main memory die stack structure and the inactive element.
